(19) United States
(12) Patent Application Publication
(10) Pub. No.: US 2011/0114152 A1
(43) Pub. Date: May 19, 2011

(54) METHOD OF MANUFACTURING PHOTOVOLTAIC CELLS, PHOTOVOLTAIC CELLS PRODUCED THEREBY AND USES THEREOF

(75) Inventors: Marat ZAKS, Krasnodar (RU); Galina Kolomoets, Krasnodar (RU); Andrey Sitnikov, Krasnodar (RU); Oleg Solodukha, Krasnodar (RU); Lev Kreinin, Bnei-Brak (IL); Naftali P. Eisenberg, Jerusalem (IL); Ninel Bordin, Tel-Aviv (IL)

(73) Assignees: Solar Wind Ltd., Krasnodar (RU); B-Solar Ltd., RaAnana (IL)

(21) Appl. No.: 12/947,842

(22) Filed: Nov. 17, 2010

Related U.S. Application Data
(63) Continuation-in-part of application No. 12/591,391, filed on Nov. 18, 2009.
Application No. 12/591,391 is a continuation-in-part of application No. 12/591,390, filed on Nov. 18, 2009.

(51) Int. Cl. H01L 31/042; H01L 31/06; H01L 31/18

(52) U.S. Cl. 136/244; 136/255; 438/71; 257/E31.13

(57) ABSTRACT

Novel methods of producing photovoltaic cells are provided herein, as well as photovoltaic cells produced thereby, and uses thereof. In some embodiments, a method as described herein comprises doping a substrate so as to form a p⁺ layer on one side and an n⁺ layer on an another side, applying an antireflective coating on the p⁺ layer, removing at least a portion of the n⁺ layer, and then forming a second n⁺ layer, such that a concentration of the n-dopant in the second n⁺ layer is variable throughout a surface of the substrate.

### RELATED APPLICATION

This application is a continuation-in-part of U.S. patent application Ser. Nos. 12/591,391 and 12/591,390 both filed on Nov. 18, 2009.

The contents of all of the above applications are incorporated by reference as if fully set forth herein.

### FIELD AND BACKGROUND OF THE INVENTION

The present invention, in some embodiments thereof, relates to energy conversion, and, more particularly, but not exclusively, to a photovoltaic cell comprising a doped semi-conductive substrate, and to methods of producing same.

Photovoltaic cells are capable of converting light directly into electricity. There is considerable hope that conversion of sunlight into electricity by photovoltaic cells will provide a significant source of renewable energy in the future, thereby enabling a reduction in the use of non-renewable sources of energy, such as fossil fuels. However, despite world-wide demand for environmentally friendly renewable energy sources, the high cost of manufacture of photovoltaic cells, as well as their limited efficiency of conversion of sunlight to electricity, has so far limited their use as a commercial source of electricity. There is therefore a strong demand for photovoltaic cells which are relatively inexpensive to produce, yet have a high efficiency.

Photovoltaic cells commonly comprise a p-type silicon substrate doped on one side thereof with an n-dopant (e.g., phosphorus) so as to form a n⁺ layer, and doped on the other side thereof with a p-dopant (e.g., boron) so as to form a p⁺ layer, thereby forming a n⁺-p-p⁺ structure. If an n-type silicon substrate is used, an n⁺-n-p⁺ structure is formed.

Electrical contacts are then applied to each side. Electrical contacts must cover only a small fraction of the surface area in order to avoid impeding the passage of light. Electrical contacts are typically applied in a grid pattern in order to avoid covering much of the surface area. Monofacial photovoltaic cells have such a grid pattern on one side of the photovoltaic cell, whereas bifacial photovoltaic cells have such a pattern on both sides of the photovoltaic cell, and can therefore collect light from any direction.

Efficiency may be improved by reducing reflectance of light from the surface of the photovoltaic cell. Methods for achieving this include texturing the surface and applying an antireflective coating. Titanium dioxide (TiO₂), ZrO₂, Ta₂O₅ and silicon nitride are examples of antireflective coatings that are currently in practice.

An exemplary process of producing a photovoltaic cell with a silica/silicon nitride stack system on the rear side is described in Kranzel et al., in a paper submitted for the 2006 IEEE 4^{th} World Conference on Photovoltaic Energy Conversion in Hawaii.

In addition, attempts to improve efficiency include producing photovoltaic cells with a selective emitter, in which the n⁺ layer is more heavily doped in regions underlying electrical contacts, in order to decrease contact resistance.

German Patent No. 102007036921 is illustrative of such an approach, disclosing a method of producing a solar cell with an n⁺-p-p⁺ structure, in which a masking layer having openings corresponding to the pattern of the contact grid is used while doping with phosphorus, so that the concentration of phosphorus will be highest under the contact grid.

U.S. Pat. No. 6,277,667 discloses a method of manufacturing a solar cell using screen printing to apply an n-dopant source to form n⁺ regions, while a low dose n-dopant source is used to form shallowly doped n⁻ regions. Electrodes are then screen-printed onto the n⁺ regions.

U.S. Pat. No. 5,871,591 discloses diffusing phosphorus into a surface of a silicon substrate, metallizing a patterned grid onto the phosphorus-doped surface, and plasma etching the phosphorus-doped surface, such that the substrate below the electrical contacts is masked and material that is not masked is selectively removed.

Another approach to achieving an n⁺ layer that is more heavily doped in regions underlying electrical contacts is the use of self-doping electrodes.

For example, U.S. Pat. No. 6,180,869 discloses a self-doping electrode to silicon formed primarily from a metal alloyed with a dopant. When the alloy is heated with a silicon substrate, dopant is incorporated into molten silicon.

Russian Patent No. 2139601 discloses a method of manufacturing a solar cell with an n⁺-p-p⁺ structure, by high-temperature processing of a silicon substrate with a borosilicate film applied to the back side thereof and a phosphosilicate film applied to the front side thereof. Removal of a layer of silicon from the front side of the substrate and texturing of the front side is then performed in one procedure. An n⁺ layer is then formed on the front side, followed by formation of contacts.

Additional background art includes U.S. Pat. No. 6,825,104, U.S. Pat. No. 6,552,414, European Patent No. 1738402 and U.S. Pat. No. 4,989,059.

### SUMMARY OF THE INVENTION

According to an aspect of some embodiments of the present invention there is provided a method of producing a photovoltaic cell, the method comprising:

a) doping a first surface of a semiconductive substrate with an n-dopant so as to form a first n⁺ layer in the substrate;

b) doping a second surface of the substrate with a p-dopant so as to form a p⁺ layer in the substrate;

c) applying an antireflective coating to the second surface, the antireflective coating comprising a substance selected from the group consisting of silicon nitride and silicon oxynitride;

d) removing a portion of the first n⁺ layer from the first surface of the substrate, such that a concentration of the n-dopant remaining in the first surface of the substrate is variable throughout the first surface;

e) doping the first surface of the substrate with an n-dopant so as to form a second n⁺ layer, such that a concentration of the n-dopant in the second n⁺ layer is variable throughout the first surface; and

f) forming electrical contacts on each of the first surface and the second surface,

thereby producing the photovoltaic cell,

wherein applying the antireflective coating is performed prior to or subsequent to removing the portion of the first n⁺ layer from the first surface, and prior to doping the first surface of the substrate with the n-dopant so as to form the second n⁺ layer.

According to an aspect of some embodiments of the present invention there is provided a photovoltaic cell produced according to a method described herein.

According to an aspect of some embodiments of the present invention there is provided a photovoltaic cell comprising a semiconductive substrate, the substrate comprising an n⁺ layer on a first surface thereof and a p⁺ layer on a second surface thereof, the n⁺ layer comprising an n-dopant and the p⁺ layer comprising a p-dopant, the second surface being coated by an antireflective coating which comprises a substance selected from the group consisting of silicon nitride and silicon oxynitride, and electrical contacts attached to each of the first surface and the second surface,

wherein the first surface is textured so as to comprise peaks and troughs, and

wherein a concentration of the n-dopant in the n⁺ layer is greater in the peaks of the first surface than in the troughs of the first surface.

According to an aspect of some embodiments of the present invention there is provided a photovoltaic array comprising a plurality of photovoltaic cells described herein, the plurality of photovoltaic cells being interconnected to one another.

According to an aspect of some embodiments of the present invention there is provided a power plant comprising a photovoltaic array described herein.

According to an aspect of some embodiments of the present invention there is provided an electric device comprising a photovoltaic cell described herein.

According to an aspect of some embodiments of the present invention there is provided a detector of electromagnetic radiation, the detector comprising a photovoltaic cell described herein, wherein the electromagnetic radiation is selected from the group consisting of ultraviolet, visible and infrared radiation.

According to some embodiments of the invention, the first n⁺ layer is characterized by a sheet resistance of less than 30 ohms.

According to some embodiments of the invention, the first n⁺ layer has a depth in a range of 0.4-2 μm.

According to some embodiments of the invention, the second n⁺ layer is characterized by a sheet resistance in a range of 30-100 ohms.

According to some embodiments of the invention, the n⁺ layer of the photovoltaic cell is characterized by a sheet resistance in a range of 30-100 ohms.

According to some embodiments of the invention, the second n⁺ layer has a depth in a range of 0.2-0.7 μm.

According to some embodiments of the invention, the n⁺ layer of the photovoltaic cell has a depth in a range of 0.2-0.7 μm.

According to some embodiments of the invention, removing the portion of the first n⁺ layer from the first surface comprises texturing the first surface.

According to some embodiments of the invention, the texturing generates peaks and troughs in the first surface, wherein a concentration of the n-dopant remaining in the first surface following texturing is greater in the peaks than in the troughs.

According to some embodiments of the invention, a concentration of the n-dopant in the second n⁺ layer is greater in the peaks than in the troughs.

According to some embodiments of the invention, a concentration of the n-dopant in the peaks in the second n⁺ layer is at least twice a concentration of the n-dopant in the troughs in the second n⁺ layer.

According to some embodiments of the invention, a concentration of the n-dopant in the peaks in the photovoltaic cell is at least twice a concentration of the n-dopant in the troughs in the photovoltaic cell.

According to some embodiments of the invention, a concentration of the n-dopant in the peaks in the second n⁺ layer is at least 5×10²⁰ atoms/cm³.

According to some embodiments of the invention, a concentration of the n-dopant in the peaks in the photovoltaic cell is at least 5×10²⁰ atoms/cm³.

According to some embodiments of the invention, a concentration of the n-dopant in the troughs in the second n⁺ layer is less than 10²¹ atoms/cm³.

According to some embodiments of the invention, a concentration of the n-dopant in the troughs in the photovoltaic cell is less than 10²¹ atoms/cm³.

According to some embodiments of the invention, removing the portion of the n⁺ layer from the first surface comprises etching the first surface to an average depth in a range of from 4 μm to 12 μm.

According to some embodiments of the invention, etching is by an alkaline solution.

According to some embodiments of the invention, the first n⁺ layer and the p⁺ layer are formed simultaneously.

According to some embodiments of the invention, the doping with the n-dopant so as to form the first n⁺ layer and the doping with the p-dopant so as to form the p⁺ layer is effected by:

(i) applying a film comprising the p-dopant to the second surface;

(ii) applying a film comprising the n-dopant to the first surface; and

(iii) heating the substrate,

thereby simultaneously forming the first n⁺ layer and the p⁺ layer.

According to some embodiments of the invention, the film comprising the p-dopant and the film comprising the n-dopant each comprise silicon dioxide.

According to some embodiments of the invention, the film comprising the p-dopant comprises boron oxide.

According to some embodiments of the invention, the film comprising the n-dopant comprises phosphorus pentoxide.

According to some embodiments of the invention, the film comprising the n-dopant comprises at least 20 weight percents phosphorus pentoxide.

According to some embodiments, the method further comprises subjecting the antireflective coating on the second surface to a thermal treatment.

According to some embodiments, the thermal treatment increases a refractive index of the antireflective coating.

According to some embodiments, the thermal treatment increases a refractive index of at least a portion of the antireflective coating by at least 0.05.

According to some embodiments, the thermal treatment simultaneously dopes the first surface of the substrate with the n-dopant so as to form the second n⁺ layer.

According to some embodiments of the invention, the method comprises applying an antireflective coating characterized by a refractive index in a range of from 2.1 to 2.2.

According to some embodiments, the antireflective coating on the second surface of the photovoltaic cell is characterized by a refractive index in a range of from 2.1 to 2.4.

According to some embodiments, the antireflective coating on the second surface is characterized by a graded refractive index which decreases from the direction of an interface with the substrate.

According to some embodiments, the method comprises applying an antireflective coating with a graded refractive index within a range of from 1.7 to 2.25.

According to some embodiments, the graded refractive index of the antireflective coating of the photovoltaic cell is within a range of from 1.7 to 2.45.

According to some embodiments, the antireflective coating applied to the second surface inhibits doping by the n-dopant of a surface coated by the antireflective coating.

According to some embodiments of the invention, the method further comprises applying an antireflective coating to the first surface subsequent to forming the second n⁺ layer.

According to some embodiments, the photovoltaic cell further comprises an antireflective coating on the first surface.

According to some embodiments of the invention, the semiconductive substrate is an n-type semiconductor prior to said doping.

According to some embodiments of the invention, the semiconductive substrate is a p-type semiconductor prior to said doping.

According to some embodiments of the invention, the semiconductive substrate comprises silicon.

According to some embodiments of the invention, the n-dopant comprises phosphorus.

According to some embodiments of the invention, the p-dopant comprises boron.

According to some embodiments of the invention, the photovoltaic cell is characterized by a short circuit current density of at least 0.033 amperes/cm².

According to some embodiments of the invention, the photovoltaic cell is characterized by a fill factor of at least 75.5%.

According to some embodiments of the invention, the photovoltaic cell is characterized by an efficiency of at least 16.7%.

According to some embodiments of the invention, the photovoltaic cell is a bifacial photovoltaic cell.

According to some embodiments of the invention, the photovoltaic cell comprises an n⁺-n-p⁺ structure.

According to some embodiments of the invention, the photovoltaic cell comprises an n⁺-p-p⁺ structure.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced. The patent or application file contains at least one drawing executed in color. Copies of this patent or patent application publication with color drawing(s) will be provided by the Office upon request and payment of the necessary fee.

In the drawings:

FIG. 1 is a scheme depicting an exemplary method for producing a photovoltaic cell according to some embodiments of the invention;

FIG. 2 is a scheme depicting another exemplary method for producing a photovoltaic cell according to some embodiments of the invention;

FIG. 3 is a graph showing the dependence of short circuit current density, J_{SC}, (in mA/cm²) on etching depth (in micrometers) in photovoltaic cells produced according to an embodiment of the invention, wherein the sheet resistance of the first n⁺ layer of the cells was 13, 17 or 25 ohm;

FIG. 4 is a graph showing the dependence of fill factor (FF) on etching depth (in micrometers) in photovoltaic cells produced according to an embodiment of the invention, wherein the sheet resistance of the first n⁺ layer of the cells was 13, 17 or 25 ohm;

FIG. 5 is a graph showing the dependence of efficiency on etching depth (in micrometers) for photovoltaic cells produced according to an embodiment of the invention, wherein the sheet resistance of the first n⁺ layer of the cells was 13, 17 or 25 ohm;

FIG. 6 is a graph showing the measured effective minority carrier lifetime (in microseconds) in silicon wafers with a p+-p-p+ structure after p+-p-p+ structure formation by boron doping (1), after silicon nitride deposition (2) and after thermal treatment of the wafer (3); and

FIG. 7 is a graph showing calculated short circuit current density (in milliamperes/cm²) of a silicon photovoltaic cell with theoretically maximal internal quantum efficiency in a medium with a refractive index of 1.45 as a function of the refractive index of the lowermost layer of a 1-layer or 2-layer antireflective coating of the photovoltaic cell.

### DESCRIPTION OF SPECIFIC EMBODIMENTS OF THE INVENTION

The present invention, in some embodiments thereof, relates to energy conversion, and, more particularly, but not exclusively, to a photovoltaic (PV) cell comprising a doped semi-conductive substrate, and to methods of producing same.

In a search for efficient, yet relatively inexpensive, photovoltaic cells for converting light energy to electrical energy, the present inventors have uncovered that a photovoltaic cell with an n-doped layer characterized by a variable concentration of an n-dopant exhibits improved efficiency.

In addition, the present inventors have conceived that when doping of a substrate to produce a photovoltaic cell is performed by doping one side of the substrate with a p-dopant followed by doping of another side with an n-dopant, efficiency of the photovoltaic cell can be enhanced by introducing a simple, inexpensive procedure for applying an antireflective coating to the p-doped surface prior to doping of the other side with an n-dopant. The antireflective coating can prevent contact of the n-dopant with the p-doped surface, thereby advantageously separating the two types of dopant. Moreover, optionally, the antireflective properties of the coating may be optimized by the same thermal treatment used to introduce the n-dopant, thereby making the process more efficient.

The present inventors have therefore devised and successfully practiced a novel methodology for producing a photovoltaic cell, which involves a reduced number of procedures in comparison with other methodologies, and is hence cost-efficient and yield-efficient, resulting in less defects during the manufacturing process. This novel methodology further results in photovoltaic cells with performance parameters that surpass many other PV cells.

While reducing the present invention to practice, the present inventors have produced a photovoltaic (PV) cell with an n⁺-p-p⁺ structure and a variable concentration of an n-dopant in the n⁺ layer, using a relatively simple, and hence relatively inexpensive, procedure. A first n⁺ layer is formed by doping and is then removed to a varying degree at different regions of the photovoltaic cell, such that the remaining n-dopant is present in a variable concentration. A second n⁺ layer is then formed by doping, and the concentration of n-dopant throughout the second n⁺ layer is variable, due to the variable nature of the removal of the first n⁺ layer.

Without being bound to any particular theory, it is believed that a variable concentration of an n-dopant in the n⁺ layer provides a combination of advantages of a high concentration of n-dopant and advantages of a low concentration of n-dopant. Thus, it is believed that the presence of randomly distributed local regions of a high concentration reduces series resistance of the photovoltaic cell, thereby increasing fill factor and efficiency of the photovoltaic cell, and that presence of regions of a low concentration increases efficiency by preventing the decrease in short circuit current which is characteristic of high dopant concentrations.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

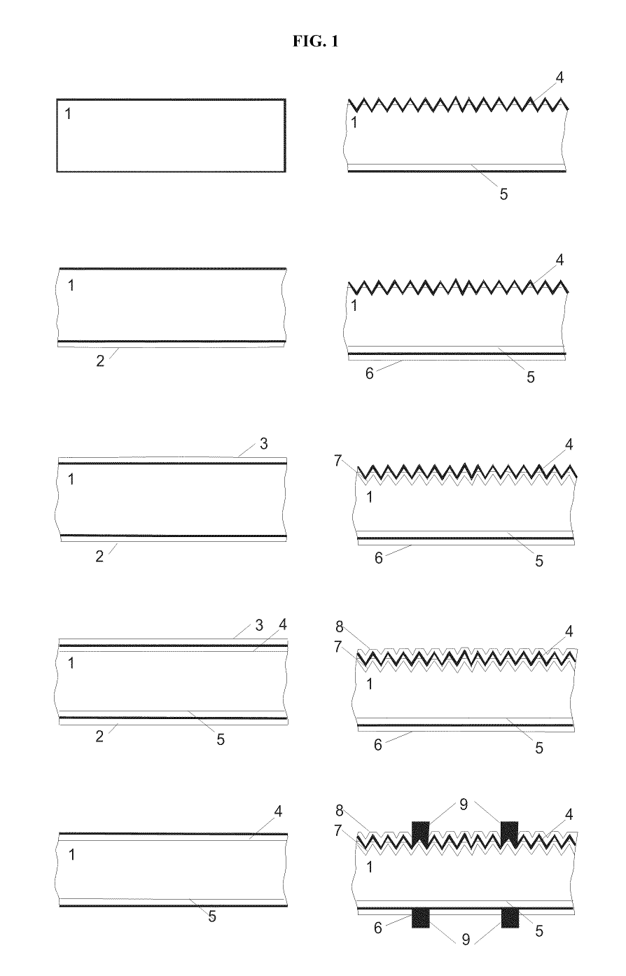

Referring now to the drawings, FIG. 1 illustrates an exemplary method for producing a photovoltaic cell according to some embodiments of the invention.

A semiconducting substrate 1 is coated on one side by a p-dopant-containing film 2. Substrate 1 is then coated with an n-dopant-containing film 3 on the side of the substrate opposite from p-dopant-containing film 2. Diffusion of dopants from the films is induced (e.g., by heating), thereby resulting in simultaneous formation of a first n⁺ layer 4 and a p⁺ layer 5. Films 2 and 3 are then removed. Substrate 1 is then textured at the surface thereof by an etching solution, resulting in peaks and troughs at the surface of the substrate (except at p⁺ layer 5, which resists texturing). First n⁺ layer 4 remains only at the peaks of the textured surface. Substrate 1 is then coated by a rear antireflection coating 6. A second n⁺ layer 7 is formed and then coated by a front antireflection coating 8. Rear antireflection coating 6 prevents second n⁺ layer 7 from contacting p⁺ layer 5 at an edge of substrate 1. Electrical contacts 9 are then formed on both sides of the substrate, to form a photovoltaic cell.

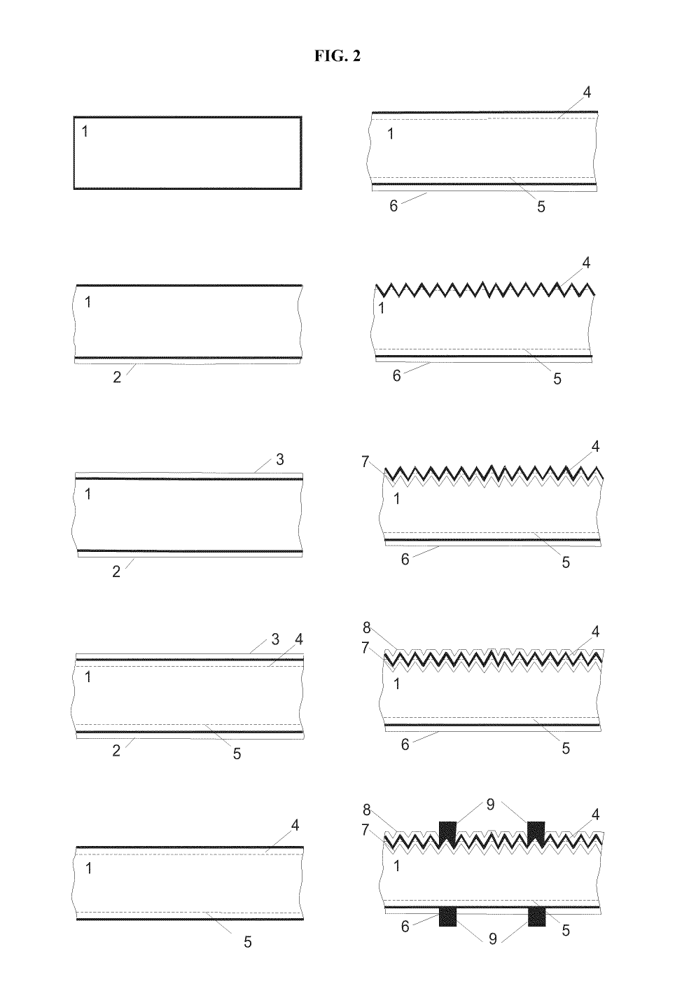

FIG. 2 illustrates another exemplary method for producing a photovoltaic cell according to some embodiments of the invention.

A semiconducting substrate 1 is coated on one side by a p-dopant-containing film 2. Substrate 1 is then coated with an n-dopant-containing film 3 on the side of the substrate opposite to p-dopant-containing film 2. Diffusion of dopants from the films is induced (e.g., by heating), thereby resulting in simultaneous formation of a first n⁺ layer 4 and a p⁺ layer 5. Films 2 and 3 are then removed. p⁺ layer 5 is then coated by a rear antireflection coating 6. Substrate 1 is then textured at the surface thereof by an etching solution, resulting in peaks and troughs at the surface of the substrate (except at rear antireflection coating 6, which resists texturing). First n⁺ layer 4 remains only at the peaks of the textured surface. A second n⁺ layer 7 is formed and then coated by a front antireflection coating 8. Rear antireflection coating 6 prevents second n⁺ layer 7 from contacting p⁺ layer 5 at an edge of substrate 1. Electrical contacts 9 are then formed on both sides of the substrate, to form a photovoltaic cell.

The above-described exemplary methods achieve a variable concentration of n-dopant, as the concentration of n-dopant is higher at the peaks of the textured surface, where n-dopant originating from formation of the second n⁺ layer 7 is present along with n-dopant remaining from the first n⁺ layer 4.

The above-described exemplary methods also result in no overlap between the p⁺ layer and n⁺ layer because the p⁺ layer is protected by the rear antireflection coating when the second n⁺ layer is formed.

In addition, the above methods are particularly advantageous in that they utilize procedures which improve efficiency of a photovoltaic cell by more than one mechanism. Thus, texturing improves efficiency of photovoltaic cells both by reducing the percentage of light wasted by reflectance from the surface of the cell and by creating a variable concentration of n-dopant. Formation and removal of a first n⁺ layer improves efficiency both by facilitating the creation of a variable concentration of n-dopant and by beneficially preventing formation of p⁺ regions within the n⁺ layer, which would detrimentally increase shunting. The rear antireflective coating both reduces reflectance and protects the p⁺ layer when forming the second n⁺ layer.

Thus, these methods do not require excessive procedures, and in fact involve less procedures than commonly utilized for producing PV cells, and none of the procedures included in these methods are particularly complex. As a result, the methods are relatively simple and inexpensive to perform. The reduced number of procedures reduces the chances of defects formation, thus render the entire process more efficient.

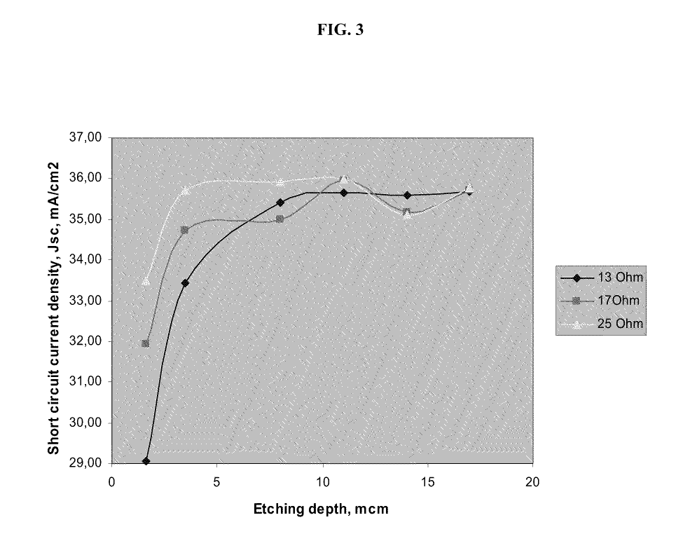

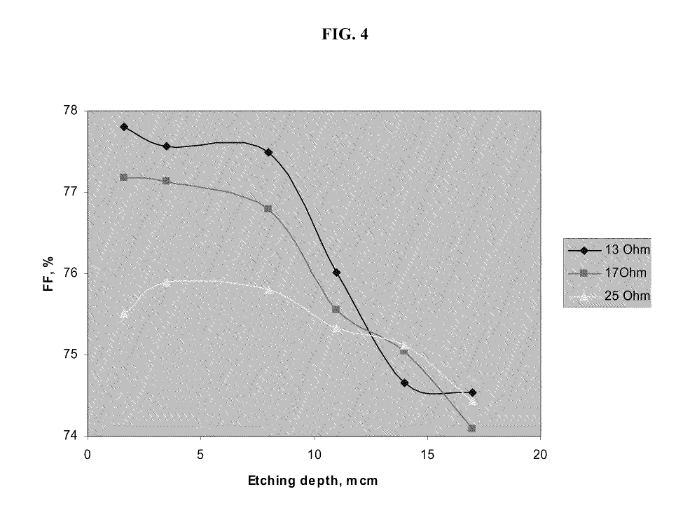

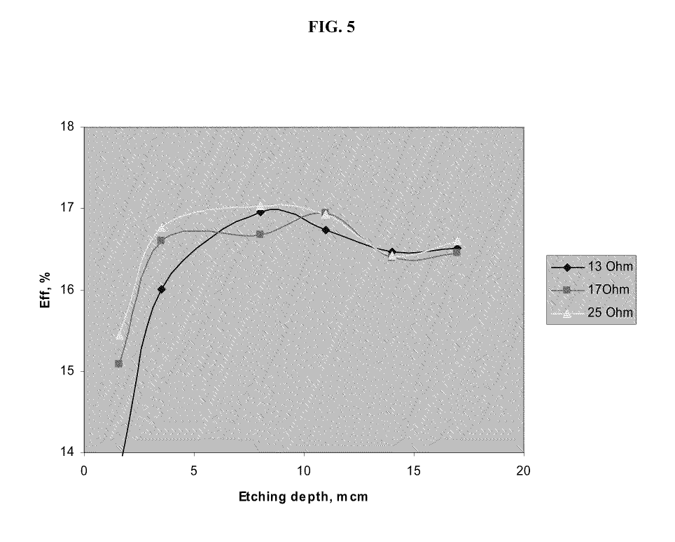

FIG. 3 shows that the short circuit current density of photovoltaic cells prepared according to embodiments of the invention is reduced when etching during texturing is relatively shallow (e.g., less than about 4 μm on average). FIG. 4 shows that the fill factor of photovoltaic cells prepared according to methods described herein is reduced when etching during texturing is relatively deep (e.g., more than about 12 μm on average). FIG. 5 shows that the efficiency (which is correlated to both fill factor and short circuit current) of photovoltaic cells prepared according to methods described herein is greatest when etching is at an intermediate depth (e.g., about 4-12 μm on average).

Without being bound to any particular theory, it is believed that shallow texturing does not create the desired variable concentration of n-dopant because not enough of the n-dopant of the first n⁺ layer is removed, while relatively deep etching does not create a variable concentration of n-dopant because virtually all of the n-dopant of the first n⁺ layer is removed. Thus, it is believed that an intermediate average depth of etching is optimal for producing a variable concentration of n-dopant, as an intermediate average depth comprises both regions with relatively deep etching (troughs) and regions with relatively shallow etching (peaks).

The above-described exemplary methods also form a non-symmetrical structure in which one side is textured and the other side is smooth (non-textured). Without being bound by any particular theory, it is believed that such a structure is advantageous when radiation is incident on the textured surface, as the textured surface decreases reflection, and the smooth, non-textured surface enhances internal reflection of long-wavelength radiation reaching the back of the cell, thereby increasing the contribution of long-wavelength radiation to the generated current. In addition, the effective surface recombination of the smooth p⁺ surface is lower than that of a textured surface, resulting in lower losses of efficiency.

However, it is further believed that the smooth rear surface is disadvantageous for bifacial photovoltaic cells in that the relatively high reflectance of the rear surface reduces the efficiency when the rear surface of the cell is illuminated. It is therefore advantageous to provide for an effective antireflective coating for the rear surface.

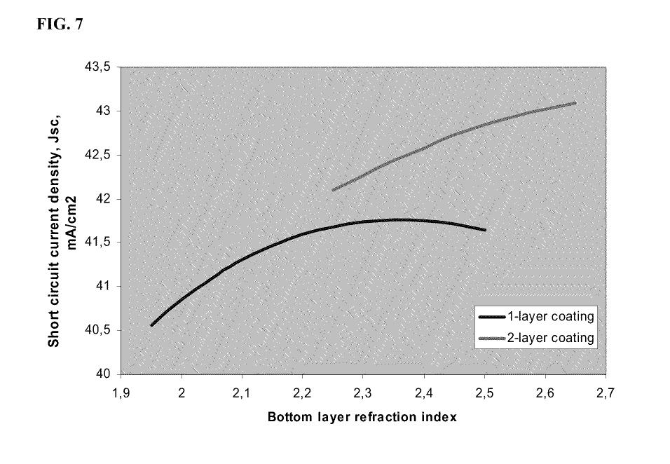

As described herein, silicon nitride and/or silicon oxynitride may be deposited on the substrate so as to form a coating with a controllable refractive index. As shown in FIG. 7, a high refractive index (e.g., 2.3 or higher) improves the effectiveness of an antireflective coating. However, silicon nitride layers with a refractive index exceeding 2.2 are characterized by increased light absorption at short wavelengths [Opto-Electronics Rev. 2004, 12:41-44], a feature which may reduce the efficiency of a photovoltaic cell. Hence, it is advantageous to deposit a coating with a refractive index of less than about 2.2 (e.g., in a range of from 2.1 to 2.2), despite the sub-optimal antireflective properties of such coatings.

Without being bound by any particular theory, it is believed that the thermal treatment of an antireflective coating described herein at least partially overcomes the above-described problem by increasing a refractive index of an antireflective coating to a more optimal level, without sacrificing the low absorption at short wavelengths which is characteristic of coatings with low refractive indices.

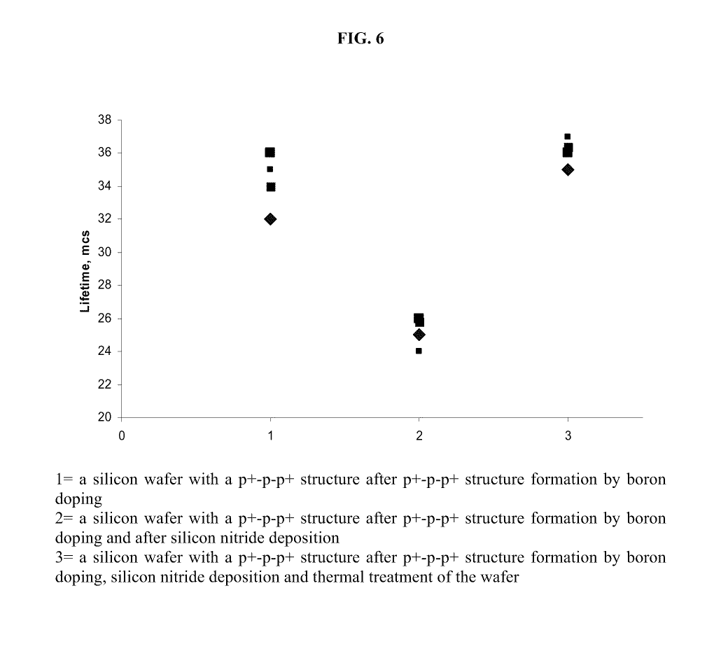

Moreover, the present inventors have uncovered that the thermal treatment of silicon nitride and/or silicon oxynitride coatings maintains a low level of surface recombination, as shown in FIG. 6, thereby enhancing the efficiency of photovoltaic cells. Thus, it is to be understood that application of an antireflective coating according to embodiments described herein can increase efficiency by mechanisms which are not necessarily related to reducing reflection.

Without being bound by any particular theory, it is believed that deposition of silicon nitride on the surface increases levels of p⁺ layer surface recombination due to the introduction of electrical charge and/or hydrogen atoms, and that thermal treatment eliminates such electrical charge and/or hydrogen atoms, thereby decreasing levels of surface recombination.

Hence, according to an aspect of some embodiments of the invention, there is provided a method of producing a photovoltaic cell, the method comprising:

a) doping a first surface of a semiconductive substrate with an n-dopant so as to form a first n⁺ layer in the substrate;

b) doping a second surface of the substrate with a p-dopant so as to form a p⁺ layer in the substrate;

c) applying an antireflective coating (e.g., comprising silicon nitride and/or silicon oxynitride) to the second surface;

d) removing a portion of the first n⁺ layer from the first surface of the substrate, such that a concentration of the n-dopant remaining in the first surface of the substrate is variable throughout the first surface;

e) doping the first surface of the substrate with an n-dopant so as to form a second n⁺ layer, such that a concentration of the n-dopant in the second n⁺ layer is variable throughout the first surface; and

f) forming electrical contacts on each of the first surface and the second surface.

The application of the antireflective coating (step c) may be performed prior to or subsequent to the removal of a portion of the first n⁺ layer (step d), but in any case is performed prior to the doping of the first surface to form a second n⁺ layer (step e). As discussed herein, such an application of an antireflective coating may be useful in preventing overlap between the p⁺ layer and the second n⁺ layer, when the antireflective coating is resistant, at least to some extent, to diffusion of the n-dopant.

Hence, in some embodiments, the antireflective coating on the second surface is impermeable, at least to some extent, to n-dopant (e.g., phosphorus), such that the coating inhibits entry of n-dopant into the p-doped regions on the second surface. Optionally, the coating reduces entry of the n-dopant into regions coated by the coating by at least 99%, optionally by at least 99.9%, and optionally by at least 99.99%. Optionally, the coating is fully impermeable to the n-dopant.

The antireflective coating may be formed by any suitable method known to the skilled artisan (e.g., chemical vapor deposition or plasma-enhanced chemical vapor deposition).

As exemplified hereinbelow in the Examples section, antireflective coatings comprising silicon nitride and/or silicon oxynitride are particularly suitable for enhancing efficiency of photovoltaic cells when applied according to procedures described herein. However, application according to the procedures described herein of antireflective coatings comprising other suitable substances (e.g., TiO₂, ZrO₂, Ta₂O₅) is also contemplated.

The antireflective coating may comprise one or more layers. When more than one layer is present, the different layers may differ, for example, in refractive index (e.g., an upper layer having a lower refractive index than a lower layer) and/or components (e.g., one layer comprising silicon oxynitride and another layer comprising silicon nitride).

According to some embodiments, the method further comprises subjecting the antireflective coating to a thermal treatment (e.g., heating), for example, a thermal treatment which increases a refractive index of the antireflective coating. Thus, for example, the refractive index of silicon nitride, an exemplary component of antireflective coatings, is increased by thermal treatment [Winderbaum et al., “INDUSTRIAL PECVD SILICON NITRIDE: SURFACE AND BULK PASSIVATION OF SILICON WAFERS”, 19th European PVSEC, Paris, France, 2004, 576-579]. Optionally, the thermal treatment increases a refractive index of at least a portion (e.g., the lowermost portion, which is closest to the silicon substrate) of the antireflective coating by at least 0.05 (e.g., increasing from below 2.2 to at least 2.25), optionally by at least 0.1 (e.g., increasing from below 2.2 to at least 2.3), and optionally by at least 0.15 (e.g., increasing from below 2.2 to at least 2.35).

Thermal treatments may be used to dope a substrate, for example, by heating the substrate in the presence of a substance (e.g., gas, paste) which comprises a dopant.

Hence, in some embodiments, the thermal treatment (e.g., a temperature in a range of from 800 to 900° C., for 10 to 30 minutes) simultaneously dopes the first surface of the substrate with an n-dopant so as to form the second n⁺ layer described hereinabove. Such embodiments advantageously allow for thermal treatment of the antireflective coating without increasing the number of procedures involved in producing a photovoltaic cell. The simultaneous heat treatment of an antireflective coating and doping with an n-dopant is exemplified in the Examples section hereinbelow. It is within the capabilities of a skilled artisan to determine conditions (e.g., temperature, time of treatment) which are suitable for both doping with an n-dopant and for optimizing the antireflective coating, based on the teachings described herein.

In some embodiments, the antireflective coating applied to the second surface is characterized by a refractive index in a range of from 2.1 to 2.2. It is to be understood that such a refractive index refers to the coating when applied, e.g., following application and before thermal treatment. Optionally, the refractive index is increased by thermal treatment, such that the refractive index in the produced photovoltaic cell is higher (e.g., in a range of from 2.15 to 2.4).

In some embodiments, the antireflective coating applied to the second surface is characterized by a graded refractive index which decreases from the direction of an interface with the substrate (i.e., the refractive index is highest at an interface with the substrate and lowest in regions of the coating which are farthest from the substrate). Optionally, the graded refractive index is in a range of from 1.7 to 2.25 (e.g., following application and before thermal treatment). Optionally, the refractive index is increased by thermal treatment, such that a graded refractive index in the finished photovoltaic cell is higher (e.g., in a range of from 1.7 to 2.45).

An antireflective coating may optionally be applied to the first surface, for example, subsequent to formation of the second n⁺ layer. Any suitable coating (e.g., Ta₂O₅, TiO₂, silicon nitride, silicon oxynitride) may be used. The antireflective coating applied subsequent to formation of the second n⁺ layer and the antireflective agent applied prior to the formation of the second n+ layer can be the same or different. Exemplary coatings comprise silicon nitride and silicon oxynitride, as for the antireflective coating applied to the second surface.

The phrase “silicon nitride”, as used herein, describes a family of substances composed substantially of silicon and nitrogen, with various stochiometries of Si and N (e.g., Si₃N₄), although some amounts of additional atoms (e.g., hydrogen) may be present as impurities.

The phrase “silicon oxynitride” refers to SiNₓO_{y}, wherein each of x and y is a positive number of up to 2 (e.g., between 0.1 and 2), and x and y are in accordance with the valence requirements of Si, N and O. Some amounts of additional atoms (e.g., hydrogen) may be present as impurities.

According to exemplary embodiments, the substrate is relatively thin and flat, such that the substrate has two surfaces on opposing sides which serve as the first and second surfaces described herein.

Silicon (e.g., silicon wafers) is an exemplary semiconductive substrate.

As is widely recognized in the art, “doping” is a process of impurity introduction in the semiconductor in which the number of free charge carriers in the doped semiconductor material can be increased, and as a result, elevation of the charge carrier density in the doped semiconductor material is effected. “p-Doping” refers to doping of a semiconductor with a substance (“dopant”) which is capable of accepting weakly-bound outer electrons from the semiconductor material. Thus p-doping, wherein “p” denotes positive, is a process of doping a semiconductor with an acceptor material, or p-type dopant, which forms “holes”, or positive charges, in the semiconductor. n-doping, wherein “n” denotes negative, is a process of doping a semiconductor with an electron donating material, or n-type dopant, which forms negative charges in the semiconductor.

As used herein, the term “dopant” refers to any element or compound, which when present in the semiconductive substrate, results in p-type or n-type conductivity. A dopant which results in p-type conductivity is referred to herein as a “p-dopant”, and is typically an acceptor of electrons, whereas a dopant which results in n-type conductivity is referred to herein as a “n-dopant”, and is typically a donor of electrons.

Boron is an exemplary p-dopant and phosphorus is an exemplary n-dopant. Optionally, arsenic is used as an n-dopant. Other p-dopants and n-dopants that are suitable for use in PV cells are also contemplated.

According to optional embodiments, the semiconductive substrate is an n-type semiconductor prior to the doping described hereinabove, which forms n⁺ and p⁺ layers. In such embodiments, the photovoltaic cell has an n⁺-n-p⁺ structure, with an n layer between the n⁺ and p⁺ layers. “n⁺” denotes a layer with relatively strong doping with an n-dopant and “p⁺” denotes a layer with relatively strong doping with a p-dopant, whereas “n” denotes a layer with weaker doping with an n-dopant.

According to alternative embodiments, the semiconductive substrate is a p-type semiconductor prior to the doping described hereinabove, which forms n⁺ and p⁺ layers. In such embodiments, the photovoltaic cell has an n⁺-p-p⁺ structure, with a p layer between the n⁺ and p⁺ layers. “n⁺” denotes a layer with relatively strong doping with an n-dopant and “p⁺” denotes a layer with relatively strong doping with a p-dopant, whereas “p” denotes a layer with weaker doping with a p-dopant.

As used herein, the phrase “variable throughout the first surface” describes a surface in which the concentration of dopant in various regions on the surface differs from the concentration of dopant in other (e.g., adjacent) regions on the surface. The concentration of n-dopant at any location on the first surface may be determined by methods known in the art, for example, by sampling a thin slice of material from the surface of the substrate and determining its elemental composition. Optionally, secondary ion mass spectroscopy (SIMS) is used to determine the n-dopant concentration. SIMS, a standard method of the art, is particularly suitable for determining local concentrations on a surface.

A further discussion of the variable concentrations of the dopant is provided hereinunder.

The electric contacts may be formed according to methods well known in the art. In order to allow light to reach the substrate of the photovoltaic cell, the contacts on at least one surface (e.g., the first surface) are configured so as to reach as much of the surface as possible while shading the surface as little as possible. For example, the contacts may optionally be configured in a grid pattern.

Optionally, the photovoltaic cell is monofacial, wherein the contacts on one surface are configured so as to allow light to pass through to the substrate, as described hereinabove, whereas the contacts on the other surface are not configured as such. For example, the surface may be completely covered by the electric contacts, as such a configuration provides ease of manufacture and high efficiency.

Alternatively, the photovoltaic cell is bifacial, wherein the contacts on both surfaces are configured so as to allow light to pass through to the substrate, thereby allowing the photovoltaic cell to produce electricity from illumination on either side of the cell. As discussed hereinabove, and exemplified hereinbelow in the Examples section that follows, application of an antireflective coating on the second surface as described herein is particularly useful in increasing the efficiency of bifacial photovoltaic cells, by reducing reflection when the second (rear) surface is illuminated.

According to some embodiments, the first n⁺ layer has a depth in a range of 0.4-2 μm. Optionally, the depth is in a range of 0.6-1.2 μm.

According to some embodiments, the first n⁺ layer is characterized by a sheet resistance of less than 30 ohm. Optionally, the sheet resistance is less than 25 ohms, optionally less than 20 ohm, and optionally less than 15 ohm. According to exemplary embodiments, the sheet resistance is in a range of from about 13 ohm to about 25 ohm.

It is to be noted that the sheet resistance of an n⁺ layer is inversely correlated to the concentration of n-dopant. The relatively low sheet resistance of the first n⁺ layer described herein thus corresponds to a relatively high concentration of n-dopant, which can decrease the short circuit current and efficiency of a photovoltaic cell.

Thus, in exemplary embodiments, the second n⁺ layer, which replaces the first n⁺ layer, is characterized by a higher sheet resistance than the relatively low sheet resistances described hereinabove for the first n⁺ layer.

According to some embodiments, the second n⁺ layer is characterized by a sheet resistance in a range of 30-100 ohm. Optionally, the sheet resistance is in a range of 40-65 ohm. According to an exemplary embodiment, the sheet resistance is about 55 ohm.

According to some embodiments, the second n⁺ layer has a depth in a range of 0.2-0.7 μm, and optionally in a range of 0.3-0.4 μm.

According to exemplary embodiments, removing of the portion of the first n⁺ layer from the first surface comprises texturing the first surface.

As used herein, the term “texturing” means to make a surface more rough (e.g., resulting in peaks and troughs on the surface).

As used herein, the term “peak” refers to a region of the surface which is higher than adjacent regions, whereas the term “trough” refers to a region of the surface which is lower than adjacent regions.

According to some embodiments, the texturing generates peaks and troughs in the first surface, wherein a concentration of the n-dopant remaining in the first surface following texturing is greater in the peaks than in the troughs. Accordingly, the variable concentration of the dopant throughout the surface is manifested in these embodiments by the different concentration of the dopant in the peaks and troughs. Thus, the concentration of n-dopant in the peaks will represent local maxima of the concentration on the surface of the substrate, whereas the concentration of n-dopant in the troughs will represent local minima. These maxima and minima of the concentration create a variable concentration.

According to some embodiments, the concentration of the n-dopant in the second n⁺ layer is greater in the peaks than in the troughs. Optionally, the concentration of the n-dopant in the peaks is at least twice a concentration of the n-dopant in the troughs. Optionally, the concentration of the n-dopant in the peaks is at least 3 times, optionally at least 5 times, and optionally at least 10 times a concentration of the n-dopant in the troughs.

According to some embodiments, a concentration of the n-dopant in the peaks in the second n⁺ layer is at least 5×10²⁰ atoms/cm³. Optionally, the concentration is at least 10²¹ atoms/cm³, optionally at least 2×10²¹ atoms/cm³, optionally at least 3×10²¹ atoms/cm³, and optionally at least 5×10²¹ atoms/cm³.

According to some embodiments, a concentration of the n-dopant in the troughs in the second n⁺ layer is less than 10²¹ atoms/cm³. Optionally, the concentration is less than 0.5×10²¹ atoms/cm³, optionally less than 0.3×10²¹ atoms/cm³, optionally less than 0.2×10²¹ atoms/cm³, and optionally less than 10²⁰ atoms/cm³.

It is to be appreciated that a “high” concentration of n-dopant in the peaks of some embodiments with a greater concentration of n-dopant in the peaks than in the troughs thereof may be somewhat lower than a “low” concentration in the troughs of another embodiment with a greater concentration of n-dopant in the peaks than in the troughs thereof. According to some embodiments, removing the portion of the first n⁺ layer from the first surface comprises etching the first surface to an average depth in a range of from 4 μm to 12 μm. Optionally, the depth is in a range of 6 μm to 10 μm.

According to some embodiments, the etching is effected by an alkaline solution (e.g., a solution that comprises sodium hydroxide).

In each of the methods described herein, the first n⁺ layer and the p⁺ layer are formed via any of the methods known in the art.

In some embodiments, whenever an n⁺ layer is deposited without forming variable concentrations of the dopant throughout the surface, applying a film comprising an n-dopant to the first surface can alternatively be effected by any method known in the art. According to some embodiments, the first n⁺ layer and the p⁺ layer are formed simultaneously (e.g., by heating).

According to exemplary embodiments, the doping with the n-dopant so as to form the first n⁺ layer and the doping with the p-dopant so as to form the p⁺ layer is effected by applying a film comprising the p-dopant to the second surface, applying a film comprising the n-dopant to the first surface, and heating the substrate, thereby simultaneously forming the first n⁺ layer and the p⁺ layer.

According to some embodiments, the film comprising the p-dopant and the film comprising the n-dopant each comprise silicon dioxide. Silicon dioxide-based films may be selectively removed following the doping procedure by hydrofluoric acid.

According to some embodiments, the film comprising the p-dopant comprises boron oxide.

According to some embodiments, the film comprising the n-dopant comprises phosphorus pentoxide (P₂O₅). Optionally, the film comprises at least 20 weight percents P₂O₅. As exemplified hereinbelow in the Examples section, the concentration of phosphorus in the first n⁺ layer and the sheet resistance of the first n⁺ layer may be readily controlled by selecting a suitable concentration of P₂O₅ in the doping film.

Without being bound by any particular theory, it is believed that formation of a first n⁺ layer simultaneously with the formation of the p⁺ layer advantageously prevents formation of p⁺ regions within the n⁺ layer, which would detrimentally increase shunting. However, a concentration and depth of n-dopant which is particularly suitable for preventing formation of deleterious p⁺ regions may be higher than a concentration and depth of n-dopant which is particularly suitable for optimal performance of the final product. Hence, it is believed that by removing at least a portion of the first n⁺ layer, the n-dopant concentration in the n⁺ layer is reduced to a more suitable level for a photovoltaic cell.

According to another aspect of embodiments of the present invention, there is provided a photovoltaic cell produced according to any of the methods described herein.

Thus, according to some embodiments, there is provided a photovoltaic cell comprising a semiconductive substrate, the substrate comprising an n⁺ layer on a first surface thereof and a p⁺ layer on a second surface thereof, the second surface being coated by an antireflective coating as described herein, and electrical contacts attached to each of the first surface and the second surface, wherein the first surface is textured so as to comprise peaks and troughs, and wherein a concentration of the n-dopant in the n⁺ layer is greater in the peaks of the first surface than in the troughs of the first surface.

It is to be appreciated that the “n⁺ layer” of the photovoltaic cells described herein corresponds to the “second n⁺ layer” which is discussed herein in the context of the methods described herein. Thus, the n⁺ layer of the photovoltaic cells may optionally be characterized by any of the features (e.g., depth, sheet resistance, local n-dopant concentration) described herein with respect to the second n⁺ layer.

Optionally, the photovoltaic cell is a bifacial photovoltaic cell.

The substrate optionally comprises silicon, the p-dopant optionally comprises boron, and the n-dopant is optionally selected from the group consisting of phosphorus and arsenic, wherein phosphorus is an exemplary n-dopant.

According to some embodiments, the fill factor of the photovoltaic cell is at least 75.5%, optionally at least 76%, optionally at least 76.5%, and optionally at least 77%.

According to some embodiments, the efficiency of the photovoltaic cell is at least 16.7%, optionally at least 16.8%, optionally, at least 16.9% and optionally at least 17%.

According to some embodiments, the short circuit current density of the photovoltaic cell is at least 0.033 amperes/cm², optionally at least 0.0335 amperes/cm², and optionally at least 0.034 amperes/cm².

The abovementioned physical parameters are determined by measurements at standard test conditions used in the art to evaluate photovoltaic cells. Standard test conditions include solar irradiance of 1,000 W/m², solar reference spectrum at AM (airmass) of 1.5 and a cell temperature 25° C.

Short circuit current density may be determined, for example, by measuring the current (I_{SC}) produced by the photovoltaic cell at short circuit (i.e., voltage=0) using standard techniques of the art. Open circuit voltage (V_{OC}) may be determined by measuring the voltage across the photovoltaic cell at open circuit (i.e., current=0) using standard techniques.

Fill factor and efficiency may be determined by measuring the maximal power output of the photovoltaic cell.

Thus, the fill factor is defined as the ratio between the maximal power and the product of short circuit current and open circuit voltage (I_{SC}×V_{OC}). The maximal power, I_{SC} and V_{OC} are determined as described hereinabove.

The efficiency may be determined by determining the maximal power as described hereinabove, and dividing by the input light irradiance of the standard test conditions.

It is to be appreciated that embodiments of the present invention do not necessarily result in increased short circuit current density. Rather, as exemplified hereinbelow in the Examples section, it is the combination of a moderately high short circuit current density with an increased fill factor which results in the high efficiencies of photovoltaic cells according to embodiments of the present invention.

According to another aspect of embodiments of the invention, there is provided a photovoltaic array comprising a plurality of any of the photovoltaic cells described herein, the photovoltaic cells being interconnected to one another.

As used herein, the phrase “photovoltaic array” describes an array of photovoltaic cells which are interconnected in series and/or in parallel. Connection of the cells in series creates an additive voltage. Connection of the cells in parallel results in a higher current. Thus, a skilled artisan can connect the cells in a manner which will provide a desired voltage and current.

The array may optionally further combine additional elements such as a sheet of glass to protect the photovoltaic cell from the environment without blocking light from reaching the photovoltaic cell and/or a base which orients the array in the direction of a source of light (e.g., for tracking the daily movement of the sun). Optionally, an inverter is present in order to convert the current to alternating current. A battery is optionally present in order to store energy generated by the photovoltaic cell.

According to another aspect of embodiments of the present invention, there is provided a power plant comprising the photovoltaic array described herein. The power plant optionally comprises a plurality of photovoltaic arrays positioned so as to maximize their exposure to sunlight.

It is to be appreciated that an optimal position and orientation of a photovoltaic array may depend on whether the photovoltaic cells therein are bifacial or monofacial.

According to another aspect of embodiments of the present invention, there is provided an electric device comprising the photovoltaic cell of claim 34. In some embodiments, the photovoltaic cells are a power source for the electric device.

Exemplary applications of the photovoltaic cells and/or the solar arrays described herein include, but are not limited to, a home power source, a hot water heater, a pocket computer, a notebook computer, a portable charging dock, a cellular phone, a pager, a PDA, a digital camera, a smoke detector, a GPS device, a toy, a computer peripheral device, a satellite, a space craft, a portable electric appliance (e.g., a portable TV, a portable lighting device), and a cordless electric appliance (e.g., a cordless vacuum cleaner, a cordless drill and a cordless saw).

According to another aspect of embodiments of the present invention, there is provided a detector of electromagnetic radiation, the detector comprising any photovoltaic cell described herein, wherein the electromagnetic radiation is selected from the group consisting of ultraviolet, visible and infrared radiation. The detector may be used, for example, in order to detect the radiation (e.g., as an infrared detector) and/or to measure the amount of radiation (e.g., in spectrophotometry).

It is expected that during the life of a patent maturing from this application many relevant doping techniques will be developed and the scope of the term “doping” is intended to include all such new technologies a priori.

As used herein the term “about” refers to ±10%

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the term “method” refers to manners, means, techniques and procedures for accomplishing a given task including, but not limited to, those manners, means, techniques and procedures either known to, or readily developed from known manners, means, techniques and procedures by practitioners of the chemical and physical arts.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

### Exemplary Preparation of Photovoltaic Cells

p-Type monocrystalline silicon pseudosquare substrates (125×125 mm) with a resistivity of 1.6 ohm were used. The crystal orientation of the substrate surface was [100]. Saw damage was removed by means of etching in a solution of 25% sodium hydroxide. The substrates were then washed in peroxide-ammoniac solution.

A film of silicon dioxide containing 50% (by weight) of boron oxide was applied to the back side of the substrates employing a spin-on method using a spin rate of 3,000 rpm.

The substrates were divided into 3 experimental groups of 60 substrates. Films of silicon dioxide containing 20%, 25% or 30% (by weight) P₂O₅ were applied to the front surface of the substrates employing the spin-on method.

Diffusion of dopants into the substrate was performed by heating for 20 minutes at a temperature of 1010° C. under a nitrogen atmosphere. The resulting p⁺ layer on the back side had sheet resistance of 25 ohm or less and a depth of approximately 1 μm. The resulting n⁺ layer on the front side exhibited sheet resistances of 25, 17 and 13 ohm when phosphosilicate films of 20%, 25% and 30%, respectively, of P₂O₅ were used.

Sheet resistances were determined using a four probe method. The depths of the n⁺ layers were determined by measuring sheet resistance and subsequently removing thin layers of the substrate by etching.

The oxide layers were then removed by a 10% solution of hydrofluoric acid. Simultaneous texturing of the front side of the substrate and removal of the n⁺ layer was performed by etching with an aqueous solution of 2% sodium hydroxide and 4% isopropyl alcohol at 80° C. Etching was performed for 5, 10, 15, 25, 30 or 35 minutes. The substrates were weighed before and after etching. The average depth of etching was determined according to a difference in weight before and after texturing.

An antireflective layer of titanium dioxide was then applied on the boron-doped surface using an atmospheric pressure chemical vapor deposition (CVD) method.

A second diffusion of phosphorus into the substrate was performed by applying a film of phosphosilicate glass containing 50% P₂O₅, and heating at a temperature of 850° C. for 20 minutes. The resulting n⁺ layer exhibited a sheet resistance of 55 ohm, and had a depth of approximately 0.35 μm. Phosphorus surface concentration was determined as described above.

The film of phosphosilicate glass was removed by a 10% solution of hydrofluoric acid. The titanium dioxide film was resistant to the hydrofluoric acid solution. An antireflective layer of silicon nitride was then applied to the front surface.

A contact pattern was applied to the both sides of the substrate employing a screen printed process. PV-156 paste (DuPont) was used for the front contact; a paste developed by Monokristal (Stavropol, Russia) was used for the back contact. Firing was performed in a Centrotherm furnace.

Laser p-n junction separation was then performed at a distance of 0.2 mm from the edge of the substrate. The parameters of solar cell performance were then measured. The results of the measurements are presented in Tables 1-3 hereinbelow. The dependence of various parameters on average etching depth during texturing is depicted graphically in FIGS. 3-5.

TABLE 1
Mean values for solar cells prepared using 30% P₂O₅ film
Sheet resistance of initial n⁺ layer = 13 ohm

| Etching | Short circuit | Open circuit | | Effi- | Shunt |
|---|---|---|---|---|---|
| depth | current (I_{SC}) | voltage | Fill factor | ciency | resistance |
| (μm) | (amperes) | (V_{OC}) (mV) | (FF) (%) | (%) | (R_{SH}) (Ohm) |
| 1.6 | 4.318 | 609 | 77.80 | 13.78 | 29 |
| 3.5 | 4.969 | 617 | 77.57 | 16.01 | 38 |
| 8 | 5.260 | 618 | 77.50 | 16.96 | 40 |
| 11 | 5.297 | 617 | 76.01 | 16.73 | 36 |
| 14 | 5.291 | 619 | 74.66 | 16.47 | 39 |
| 17 | 5.303 | 620 | 74.54 | 16.51 | 35 |

TABLE 2
Mean values for solar cells prepared using 25% P₂O₅ film
Sheet resistance of initial n⁺ layer = 17 ohm

| Etching | Short circuit | Open circuit | | Effi- | Shunt |
|---|---|---|---|---|---|
| depth | current (I_{SC}) | voltage | Fill factor | ciency | resistance |
| (μm) | (amperes) | (V_{OC}) (mV) | (FF) (%) | (%) | (R_{SH}) (Ohm) |
| 1.6 | 4.747 | 611 | 77.18 | 15.08 | 33 |
| 3.5 | 5.158 | 620 | 77.14 | 16.60 | 40 |
| 8 | 5.201 | 620 | 76.79 | 16.68 | 47 |
| 11 | 5.344 | 624 | 75.55 | 16.95 | 30 |
| 14 | 5.225 | 621 | 75.04 | 16.40 | 42 |
| 17 | 5.305 | 622 | 74.09 | 16.45 | 30 |

TABLE 3
Mean values for solar cells prepared using 20% P₂O₅ film
Sheet resistance of initial n⁺ layer = 25 ohm

| Etching | Short circuit | Open circuit | | Effi- | Shunt |
|---|---|---|---|---|---|
| depth | current (I_{SC}) | voltage | Fill factor | ciency | resistance |
| (μm) | (amperes) | (V_{OC}) (mV) | (FF) (%) | (%) | (R_{SH}) (ohm) |
| 1.6 | 4.977 | 610 | 75.51 | 15.44 | 28 |
| 3.5 | 5.305 | 619 | 75.89 | 16.77 | 36 |
| 8 | 5.340 | 625 | 75.81 | 17.03 | 39 |
| 11 | 5.349 | 624 | 75.33 | 16.93 | 39 |
| 14 | 5.218 | 622 | 75.12 | 16.42 | 54 |
| 17 | 5.316 | 623 | 74.43 | 16.60 | 37 |

For several of the samples prepared, determination of phosphorus surface concentration after both the first and second diffusion of phosphorus (i.e., in both the first n⁺ layer and the second n⁺ layer) was performed using SIMS (secondary ion mass spectrometry). Based on these measurements, the concentration of phosphorus in both the peaks and in the troughs of the photovoltaic cells was estimated. The expected concentration in the troughs was the concentration measured after the second diffusion of phosphorus, whereas the expected concentration in the peaks was the sum of phosphorus concentrations measured after the first and second diffusions. The results are summarized in Table 4.

TABLE 4
Mean values for phosphorous surface concentrations
and expected concentrations for peaks and troughs.

| Initial sheet resistance (Ohm) | 13 | 17 | 25 |
|---|---|---|---|
| Surface concentration of phosphorus | ~8 × 10²⁰ | ~5 × 10²⁰ | ~3 × 10²⁰ |
| after first diffusion (atoms/cm³) | | | |
| Surface concentration of phosphorus | ~3 × 10²⁰ | | |
| after second diffusion (atoms/cm³) | | | |
| Expected concentration of phosphorus | ~1.1 × 10²¹ | ~0.8 × 10²¹ | ~0.6 × 10²¹ |
| for peaks, (atoms/cm³) | | | |

| | |
|---|---|
| Expected concentration of phosphorus | ~3 × 10²⁰ |
| for troughs, (atoms/cm³) | |

As a control, 25 solar cells were prepared as described in Russian Patent No. 2139601. In this procedure, an initial n⁺ layer was formed by applying a silicon dioxide film containing 15% (by weight) P₂O₅ to the front surface. The resulting initial n⁺ layer had a sheet resistance of 35 ohm and a depth of 1.2 μm. The mean values of the parameters of the control solar cells were as follows: V_{OC}=616 mV, J_{SC}=35.9 mA/cm², efficiency=16.2%

As shown in FIG. 3, the short circuit current density (J_{SC}) of the solar cells depended on the depth of etching during texturing, and was maximal at average etching depths of more than approximately 4 μm.

As shown in FIG. 4, the fill factor (FF) of the solar cells depended on the depth of etching during texturing, and was maximal when the average etching depth was less than approximately 8 μm.

As shown in FIG. 5, the efficiency of the solar cells depended on the etching depth, and was maximal when the average etching depth was in a range of approximately 4-12 μm.

As shown in Tables 1-3 and in FIG. 5, the efficiency of the solar cells was higher than that of the efficiency of the control cells (16.2%), and efficiencies of over 17% were obtained. The relative gain in efficiency over control values was approximately 3-5%.

These results show that the formation of an initial n⁺ layer and its removal by etching, as described hereinabove, results in high solar cell efficiency when the etching depth is within an optimal range for which relatively high values of both short circuit current and fill factor are obtained.

### Example 2

### Effect of Antireflective Coatings on Photovoltaic Cell Performance Photovoltaic cells were prepared as described in Example 1 with an initial n⁺ layer having a sheet resistance of 25 ohm and an etching depth of 8 μm. Laser p-n junction separation was performed at a distance of 0.2 mm from the edge of the substrate.

As described in Example 1, an antireflective coating was applied to the boron-doped surface before formation of the final n⁺ layer by phosphorus-doping, and an antireflective coating was applied to the final n⁺ layer following phosphorus-doping.

In one group, application of the antireflective layer on each side of the photovoltaic cell comprised forming a 75 nm layer of titanium oxide (refractive index=2.2) using an atmospheric pressure chemical vapor deposition (CVD) method, as described in Example 1.

In a second group, application of the antireflective layer on each side of the photovoltaic cell comprised forming a 60 nm layer of silicon nitride (refractive index=2.2) followed by forming an ˜80 nm layer of silicon oxynitride (refractive index=1.7) using a plasma-enhanced chemical vapor deposition (PECVD) method.

The photovoltaic cells were than laminated with a poly(ethyl-vinyl acetate) (EVA) film (refractive index=1.45).

As a control, photovoltaic cells were also prepared as described in Russian Patent No. 2139601.

The performance of the photovoltaic cells was measured under both front illumination (illumination of the n-doped surface) and back illumination (illumination of the p-doped surfaced). The effect of the antireflective layers on various parameters of photovoltaic cell performance is shown in Table 5.

TABLE 5
Mean values of solar cells with different antireflective coatings.

| | Short circuit | Open circuit | | Effi- |
|---|---|---|---|---|
| | current, I_{SC} | voltage, V_{OC} | Fill factor, | ciency |
| | (Amperes) | (mV) | FF (%) | (%) |
| | Front illumination | | | |
| Control | 5.334 | 615 | 73.25 | 16.17 |
| TiO₂ coating | 5.346 | 625 | 75.66 | 17.01 |
| Silicon nitride/silicon | 5.358 | 626 | 75.68 | 17.08 |
| oxynitride coating | | | | |
| | Back illumination | | | |
| Control | 3.389 | 612 | 75.10 | 10.48 |
| TiO₂ coating | 3.612 | 617 | 75.98 | 11.39 |
| Silicon nitride/silicon | 3.784 | 618 | 76.11 | 11.97 |
| oxynitride coating | | | | |

As shown in Table 5, the efficiency of the solar cells was higher than the efficiency of the control cells for both front and back illumination. As further shown in Table 5, the silicon nitride/oxynitride antireflective coating provided improved efficiency relative to the TiO₂ coating, particularly for back illumination.

### Example 3

### Measurements of Effective Minority Carrier Lifetime

In order to determine the effect of silicon nitride deposition on surface recombination, the effective minority carrier lifetime was determined in p⁺-p-p⁺ structures. p⁺-p-p⁺ structures were used instead of the n⁺-p-p⁺ structure of a photovoltaic cell in order to simplify interpretation of the experimental results.

4 samples were prepared from 1 ohm.cm silicon wafers, which were doped on both sides with boron by applying a film of silicon dioxide containing 50% (by weight) of boron oxide to the back side of the substrates, and then heating for 20 minutes at a temperature of 1010° C. under a nitrogen atmosphere. A 60 nm layer of silicon nitride (refractive index=2.2) was then deposited on both sides of the wafer using a plasma-enhanced chemical vapor deposition (PECVD) method, and the wafer was then subjected to thermal treatment at a temperature of 850° C. for 20 minutes.

The lifetime values were determined from decay of injected carrier concentration at the various stages.

As shown in FIG. 6, the effective carrier lifetime values decreased after silicon nitride deposition and were then fully restored after thermal treatment.

These results indicate that thermal treatment of the antireflective coating increases carrier lifetime by reducing surface recombination in the p⁺ layer, thereby improving photovoltaic cell performance.

### Example 4

### Effect of Coating Refractive Index on Photovoltaic Cell Current

The effect of the refractive index of an antireflective coating on short circuit current density (J_{SC}) of a photovoltaic cell was calculated for 1-layer and 2-layer coatings.

For the purposes of the calculation, the photovoltaic cell was assumed to be a silicon-based photovoltaic cell with theoretically maximal internal quantum efficiency and a smooth surface, within an optical medium with a refractive index of 1.45 (the refractive index of poly(ethylene-vinyl acetate)).

For a 1-layer coating, J_{SC} was calculated for each given refractive index of the coating as a function of coating thickness, and the J_{SC} at the optimal coating thickness (i.e., J_{SC} for a coating thickness at which J_{SC} is maximal) was determined.

For a 2-layer coating, J_{SC} was calculated for each given refractive index and for different thicknesses of the lower layer (the layer adjacent to the silicon surface) of the coating as a function of refractive index and thickness of the upper layer, and the J_{SC} at the optimal upper layer refractive index (i.e., J_{SC} for a coating thickness and upper layer refractive index at which J_{SC} is maximal) was determined.

As shown in FIG. 7, short circuit current density is highest when the refractive index of the antireflective coating (or of the lower layer of the antireflective coating when there is more than one layer in the coating) is at least approximately 2.3.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A method of producing a photovoltaic cell, the method comprising:
a) doping a first surface of a semiconductive substrate with an n-dopant so as to form a first n⁺ layer in said substrate;
b) doping a second surface of said substrate with a p-dopant so as to form a p⁺ layer in said substrate;
c) applying an antireflective coating to said second surface, said antireflective coating comprising a substance selected from the group consisting of silicon nitride and silicon oxynitride;
d) removing a portion of said first n⁺ layer from said first surface of said substrate, such that a concentration of said n-dopant remaining in said first surface of said substrate is variable throughout said first surface;
e) doping said first surface of said substrate with an n-dopant so as to form a second n⁺ layer, such that a concentration of said n-dopant in said second n⁺ layer is variable throughout said first surface; and
forming electrical contacts on each of said first surface and said second surface,
thereby producing said photovoltaic cell,
wherein said applying said antireflective coating to said second surface is performed prior to or subsequent to said removing said portion of said first n⁺ layer from said first surface, and prior to said doping said first surface of said substrate with said n-dopant so as to form said second n⁺ layer.

2. The method of claim 1, wherein said first n⁺ layer is characterized by a sheet resistance of less than 30 ohms.

3. The method of claim 1, wherein said first n⁺ layer has a depth in a range of 0.4-2 μm.

4. The method of claim 1, wherein said second n⁺ layer is characterized by a sheet resistance in a range of 30-100 ohms.

5. The method of claim 1, wherein said second n⁺ layer has a depth in a range of 0.2-0.7 μm.

6. The method of claim 1, wherein said removing said portion of said first n⁺ layer from said first surface comprises texturing said first surface.

7. The method of claim 6, wherein said texturing generates peaks and troughs in said first surface, wherein a concentration of said n-dopant remaining in said first surface following texturing is greater in said peaks than in said troughs.

8. The method of claim 7, wherein a concentration of said n-dopant in said second n⁺ layer is greater in said peaks than in said troughs.

9. The method of claim 8, wherein a concentration of said n-dopant in said peaks in said second n⁺ layer is at least twice a concentration of said n-dopant in said troughs in said second n⁺ layer.

10. The method of claim 8, wherein a concentration of said n-dopant in said peaks in said second n⁺ layer is at least 5×10²⁰ atoms/cm³.

11. The method of claim 8, wherein a concentration of said n-dopant in said troughs in said second n⁺ layer is less than 10²¹ atoms/cm³.

12. The method of claim 1, wherein removing said portion of said n⁺ layer from said first surface comprises etching said first surface to an average depth in a range of from 4 μm to 12 μm.

13. The method of claim 1, wherein said first n⁺ layer and said p⁺ layer are formed simultaneously.

14. The method of claim 13, wherein said doping with said n-dopant so as to form said first n⁺ layer and said doping with said p-dopant so as to form said p⁺ layer is effected by:
(i) applying a film comprising said p-dopant to said second surface;
(ii) applying a film comprising said n-dopant to said first surface; and
(iii) heating said substrate,
thereby simultaneously forming said first n⁺ layer and said p⁺ layer.

15. The method of claim 1, wherein said substrate is an n-type semiconductor prior to said doping.

16. The method of claim 1, wherein said substrate is a p-type semiconductor prior to said doping.

17. The method of claim 1, wherein said antireflective coating is characterized by a refractive index in a range of from 2.1 to 2.2.

18. The method of claim 1, wherein said antireflective coating is characterized by a graded refractive index which decreases from the direction of an interface with said substrate.

19. The method of claim 18, wherein said graded refractive index is within a range of from 1.7 to 2.25.

20. The method of claim 1, further comprising subjecting said antireflective coating to thermal treatment.

21. The method of claim 20, wherein said thermal treatment increases a refractive index of said antireflective coating.

22. The method of claim 20, wherein said thermal treatment simultaneously dopes said first surface of said substrate with said n-dopant so as to form said second n⁺ layer.

23. The method of claim 1, wherein said antireflective coating applied to said second surface inhibits doping by said n-dopant of a surface coated by said antireflective coating.

24. A photovoltaic cell produced according to the method of claim 1.

25. The photovoltaic cell of claim 24, characterized by a short circuit current density of at least 0.033 amperes/cm².

26. The photovoltaic cell of claim 24, characterized by a fill factor of at least 75.5%.

27. The photovoltaic cell of claim 24, characterized by an efficiency of at least 16.7%.

28. The photovoltaic cell of claim 24, being a bifacial photovoltaic cell.

29. A photovoltaic cell comprising a semiconductive substrate, said substrate comprising an n⁺ layer on a first surface thereof and a p⁺ layer on a second surface thereof, said n⁺ layer comprising an n-dopant and said p⁺ layer comprising a p-dopant, said second surface being coated by an antireflective coating which comprises a substance selected from the group consisting of silicon nitride and silicon oxynitride, and electrical contacts attached to each of said first surface and said second surface,
wherein said first surface is textured so as to comprise peaks and troughs, and
wherein a concentration of said n-dopant in said n⁺ layer is greater in said peaks of said first surface than in said troughs of said first surface.

30. The photovoltaic cell of claim 29, wherein said n⁺ layer is characterized by a sheet resistance in a range of 30-100 ohm.

31. The photovoltaic cell of claim 29, wherein said n⁺ layer has a depth in a range of 0.2-0.7 μm.

32. The photovoltaic cell of claim 29, wherein a concentration of said n-dopant in said peaks is at least twice a concentration of said n-dopant in said troughs.

33. The photovoltaic cell of claim 29, wherein said antireflective coating is characterized by a refractive index in a range of from 2.1 to 2.4.

34. The photovoltaic cell of claim 29, wherein said antireflective coating is characterized by a graded refractive index which decreases from the direction of an interface with said substrate.

35. The photovoltaic cell of claim 34, wherein said graded refractive index is within a range of from 1.7 to 2.45.

36. The photovoltaic cell of claim 29, characterized by a short circuit current density of at least 0.033 amperes/cm².

37. The photovoltaic cell of claim 29, characterized by a fill factor of at least 75.5%.

38. The photovoltaic cell of claim 29, characterized by an efficiency of at least 16.7%.

39. The photovoltaic cell of claim 29, being a bifacial photovoltaic cell.

40. The photovoltaic cell of claim 25, comprising an n⁺-n-p⁺ structure.

41. The photovoltaic cell of claim 25, comprising an n⁺-p-p⁺ structure.

42. A photovoltaic array comprising a plurality of the photovoltaic cell of claim 24, said plurality of photovoltaic cells being interconnected to one another.

43. A photovoltaic array comprising a plurality of the photovoltaic cell of claim 29, said plurality of photovoltaic cells being interconnected to one another.

44. A power plant comprising the photovoltaic array of claim 42.

45. A power plant comprising the photovoltaic array of claim 43.

46. An electric device comprising the photovoltaic cell of claim 24.

47. An electric device comprising the photovoltaic cell of claim 29.
